(19) United States
(12) Patent Application Publication
(10) Pub. No.: US 2015/0241517 A1
(43) Pub. Date: Aug. 27, 2015

(54) Method For Calculating Remaining Capacity Of Power Battery Pack

(71) Applicant: Ningde Contemporary Amperex Technology Limited, Ningde (CN)

(72) Inventors: Mingjun ZHUANG, Ningde (CN); Chunqing LI, Ningde (CN)

(21) Appl. No.: 14/592,791

(22) Filed: Jan. 8, 2015

(30) Foreign Application Priority Data
Feb. 25, 2014 (CN) 201410063246.3

(51) Int. Cl. G01R 31/36

(52) U.S. Cl. CPC G01R 31/3606; G01R 31/3648

(57) ABSTRACT

The present disclosure provides a method for calculating a remaining capacity of a power battery pack, which comprises steps of: (1) performing charging and discharging tests on a power battery pack provided with a battery management system with a charge-discharge machine; (2) reading C_{Bench}_{_{—}}_{c} and C_{Bench}_{_{—}}_{d} of the charge-discharge machine and reading C_{BMS}_{_{—}}_{c} and C_{BMS}_{_{—}}_{d} of the battery management system; (3) determining a charging correction coefficient K_{c} and a discharging correction coefficient K_{d},

$${K}_{c} = \frac{{C}_{Bench\_c}}{{C}_{BMS\_c}} , {K}_{d} = \frac{{C}_{Bench\_d}}{{C}_{BMS\_d}} ; \qquad ( 4 )$$

determining a remaining capacity of the power battery pack: when the power battery pack is in a charged state, a variation of capacity ΔC_{c} of the power battery pack is ΔC_{c}=K_{c}×I×Δt, the remaining capacity Cₜ of the power battery pack is Cₜ=C₀+ΔC_{c}; when the power battery pack is in a discharged state, a variation of capacity ΔC_{d} of the power battery pack is ΔC_{d}=K_{d}×I×Δt, the remaining capacity Cₜ of the power battery pack is Cₜ=C₀−ΔC_{d}.

### CROSS-REFERENCE TO RELATED APPLICATIONS

The present application claims priority to Chinese patent application No. 201410063246.3 filed on Feb. 25, 2014, which is incorporated herein by reference in its entirety.

### TECHNICAL FIELD OF THE PRESENT DISCLOSURE

The present disclosure relates to a field of power battery packs, and particularly relates to a method for calculating a remaining capacity of a power battery pack.

### BACKGROUND OF THE PRESENT DISCLOSURE

In a battery pack, a State of Charge (SOC) of the battery pack is an important parameter, which characterizes an energy level that a battery management system can provide at present. A key task of a battery management system (BMS) of an electric vehicle is to predict the State of Charge (SOC) of the battery pack. A magnitude of SOC value directly reflects a state of the battery pack, which can define a maximum charging and discharging current of the battery pack, and predict a running time of the battery pack.

A method for estimating SOC includes an open-circuit voltage method, an internal resistance method, an ampere-hour integral method, at present, many new methods for estimating SOC of the battery have been developed, such as a Kalman filter estimation model algorithm. A capacity cumulative integral process of the ampere-hour integral method is:

A present remaining capacity is:

C₀=C_{R}×SOC₀

Where, C₀ is a present remaining capacity, SOC₀ is a SOC value of the battery pack, C_{R} is a nominal capacity of the battery pack.

After a (predetermined) time quantum Δt, a cumulative capacity (charging or discharging) in this process is calculated according to a present current value of the battery pack.

A variation of capacity ΔCₜ in the charging and discharging process is: ΔCₜ=I×Δt

The remaining capacity at a moment of time t is:

Cₜ=C₀±ΔCₜ

The charging process adopts the plus sign +, the discharging process adopts the minus sign −.

Finally a SOC value at the moment of time t is calculated:

That is

$${SOC}_{t} = \frac{{C}_{t}}{{C}_{R}}$$

In the above process, a calculation error of the remaining capacity of the battery pack comes from two aspects: the current value and the time. Because a value of a current sensor must have an error, a single-chip crystal oscillator time also has an error. An error of the remaining capacity cumulative integral value nearly increases linearly as time increases.

### SUMMARY OF THE PRESENT DISCLOSURE

In view of the problem existing in the background, an object of the present disclosure is to provide a method for calculating a remaining capacity of a power battery pack, which can reduce a calculation error.

In order to achieve the above object, the present disclosure provides a method for calculating a remaining capacity of a power battery pack, which comprises steps of:

(1) performing charging and discharging tests on a power battery pack provided with a battery management system with a charge-discharge machine;

(2) reading a charging capacity cumulative integral value C_{Bench}_{_{—}}_{c} of the charge-discharge machine and a discharging capacity cumulative integral value C_{Bench}_{_{—}}_{d} of the charge-discharge machine from a host computer of the charge-discharge machine, and reading a charging capacity cumulative integral value C_{BMS}_{_{—}}_{c} of the battery management system and a discharging capacity cumulative integral value C_{BMS}_{_{—}}_{d} of the battery management system from a CAN message of the battery management system;

(3) determining a charging correction coefficient K_{c} and a discharging correction coefficient K_{d},

where

the charging correction coefficient K_{c} is:

$${K}_{c} = \frac{{C}_{Bench\_c}}{{C}_{BMS\_c}}$$

the discharging correction coefficient K_{d} is:

$${K}_{d} = \frac{{C}_{Bench\_d}}{{C}_{BMS\_d}} ;$$

(4) determining a remaining capacity of the power battery pack:

when the power battery pack is in a charged state, a variation of capacity ΔC_{c} of the power battery pack after a time quantum Δt is ΔC_{c}=K_{c}×I×Δt, where, I is a charging current flowing through the power battery pack, the remaining capacity Cₜ of the power battery pack is obtained by calculating by Cₜ=C₀+ΔC_{E};
when the power battery pack is in a discharged state, a variation of capacity ΔC_{d} of the power battery pack after a time quantum Δt is ΔC_{d}=K_{d}×I×Δt, where, I is a discharging current flowing through the power battery pack, the remaining capacity Cₜ of the power battery pack is obtained by calculating by Cₜ=C₀ ΔC_{d}.

The present disclosure has the following beneficial effects:

The charging correction coefficient K_{c} and the discharging correction coefficient K_{d} are introduced, which can reduce a calculation error of the remaining capacity of the power battery pack.

### BRIEF DESCRIPTION OF THE FIGURES

FIG. 1 is a flow chart of a method for calculating a remaining capacity of a power battery pack according to the present disclosure;

FIG. 2 was a diagram of a deviation of SOC which was not corrected and a deviation of SOC which was corrected only by K_{c};

FIG. 3 was a diagram of a deviation of SOC which was not corrected and a deviation of SOC which was corrected only by K_{d};

FIG. 4 was a diagram of a deviation of SOC which was not corrected and a deviation of SOC which was corrected by K_{c} and K_{d}.

### DETAILED DESCRIPTION

Hereinafter a method for calculating a remaining capacity of a power battery pack according to the present disclosure will be described in detail in combination with the Figures.

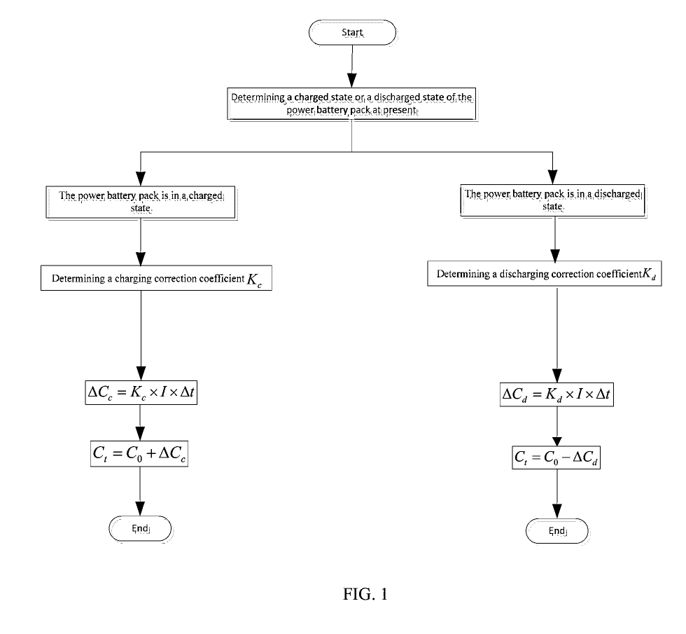

Referring to FIG. 1, a method for calculating a remaining capacity of a power battery pack according to the present disclosure comprises steps of:

(1) performing charging and discharging tests on a power battery pack provided with a battery management system with a charge-discharge machine;

(2) reading a charging capacity cumulative integral value C_{Bench}_{_{—}}_{c} of the charge-discharge machine and a discharging capacity cumulative integral value C_{Bench}_{_{—}}_{d} of the charge-discharge machine from a host computer of the charge-discharge machine, and reading a charging capacity cumulative integral value C_{BMS}_{_{—}}_{c} of the battery management system and a discharging capacity cumulative integral value C_{BMS}_{_{—}}_{d} of the battery management system from a CAN message of the battery management system;

(3) determining a charging correction coefficient K_{c} and a discharging correction coefficient K_{d},

where

the charging correction coefficient K_{c} is:

$${K}_{c} = \frac{{C}_{Bench\_c}}{{C}_{BMS\_c}}$$

the discharging correction coefficient K_{d} is:

$${K}_{d} = \frac{{C}_{Bench\_d}}{{C}_{BMS\_d}} ;$$

(4) determining a remaining capacity of the power battery pack:

when the power battery pack is in a charged state, a variation of capacity ΔC_{c} of the power battery pack after a time quantum Δt is ΔC_{c}=K_{c}×I×Δt, where, I is a charging current flowing through the power battery pack, the remaining capacity Cₜ of the power battery pack is obtained by calculating by Cₜ=C₀+ΔC_{c};

when the power battery pack is in a discharged state, a variation of capacity ΔC_{d} of the power battery pack after a time quantum Δt is ΔC_{d}=K_{d}×I×Δt, where, I is a discharging current flowing through the power battery pack, the remaining capacity C, of the power battery pack is obtained by calculating by Cₜ=C₀ ΔC_{d}.

In the method for calculating the remaining capacity of the power battery pack according to the present disclosure, the charge-discharge machine may be an AV900 power processing system, a current of the charge-discharge machine may be 0 C˜1 C.

In the method for calculating the remaining capacity of the power battery pack according to the present disclosure, the charging and discharging tests are cycles of full charging and full discharging.

In the method for calculating the remaining capacity of the power battery pack according to the present disclosure, values of K_{c} and K_{d} are 0.8˜1.2. In an embodiment, when the values of K_{c} and K_{d} are not within the range of 0.8˜1.2, the values of K_{c} and K_{d} are 1 as default.

In the method for calculating the remaining capacity of the power battery pack according to the present disclosure, the battery management system is a BSB-1XX of Shenzhen Batt Sister Science and Technology Co., Ltd.

Finally, the method for calculating the remaining capacity of the power battery pack of the present disclosure would be verified.

A 86 Ah power battery pack was connected to a battery management system (BSB-1XX of Shenzhen Batt Sister Science and Technology Co., Ltd), then charging and discharging tests were performed on the charge-discharge machine (AV900, a charging and discharging current is 0.3 C), and a deviation between SOC values calculated separately by the charge-discharge machine and the battery management system was used for verification.

Principle was: the method for calculating the remaining capacity by the charge-discharge machine and the battery management system was the same, which was the ampere-hour integral method, the charge-discharge machine had a high current and time precision, so the charge-discharge machine had an accurate ampere-hour integral value, but the battery management system had a poor current and time precision, so the ampere-hour integral value (that was the remaining capacity) calculated only by the battery management system was not accurate. Therefore, the charge-discharge machine would be a standard reference, the calculation accuracy of the remaining capacity was verified based on this standard reference and based on a deviation of SOC between the charge-discharge machine and the battery management system.

dSOC=SOC_{Bench}−SOC_{BMS}

where SOC_{Bench} was a SOC value calculated by the charge-discharge machine, the Bench calculation process was

$${SOC}_{Bench} = \frac{{C}_{t}}{{C}_{R}} ;$$

SOC_{BMS} was a SOC value calculated by the battery management system, the calculation process was

$${SOC}_{BMS} = \frac{{C}_{t}}{{C}_{R}} .$$

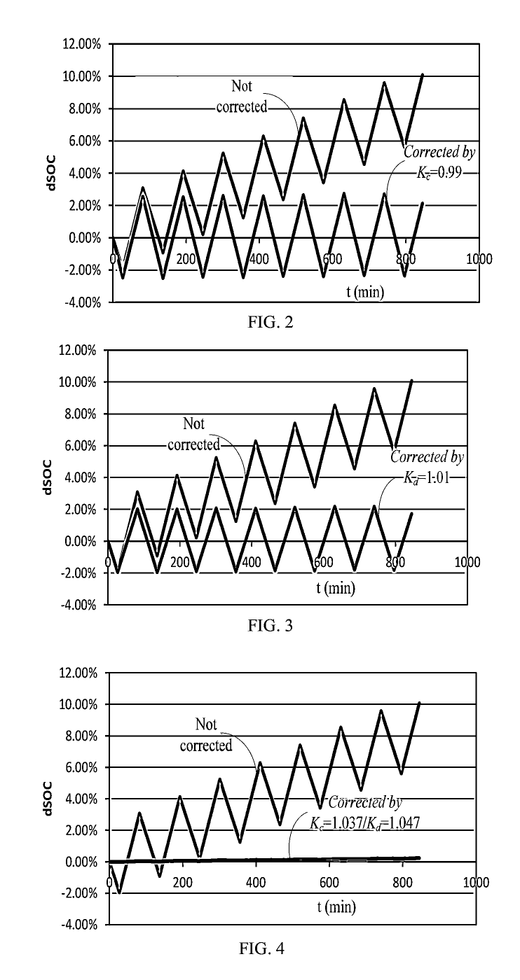

FIG. 2 was a diagram of a deviation of SOC which was not corrected and a deviation of SOC which was corrected only by K_{c}. As shown in FIG. 2, when a value of K_{c}=0.99 was introduced for correction, a deviation of SOC, dSOC, was significantly improved. Specifically, a dSOC curve in which the K_{c} value was not introduced for correction was at one side of a horizontal axis, and the degree of deviation from the horizontal axis in the dSOC curve increased with time; but a dSOC curve in which the K_{c} value was introduced for correction fluctuated up and down with the horizontal axis as the center.

FIG. 3 was a diagram of a deviation of SOC which was not corrected and a deviation value of SOC which was corrected only by K_{d}. As shown in FIG. 3, when a value of K_{d}=1.01 was introduced for correction, a deviation of SOC, dSOC, was significantly improved. Specifically, a dSOC curve in which the K_{d} value was not introduced for correction was at one side of the horizontal axis, and the degree of deviation from the horizontal axis in the dSOC curve increased with time; but a dSOC curve in which the K_{d} value was introduced for correction fluctuated up and down with the horizontal axis as the center.

FIG. 4 was a diagram of a deviation of SOC which was not corrected and a deviation of SOC which was corrected by K_{c} and K_{d}. As shown in FIG. 4, when a value of K_{c}=1.037 and K_{d}=1.047 were introduced for correction, a deviation of SOC, dSOC, was significantly improved, the accuracy was high. Specifically, a dSOC curve in which the K_{c} value and K_{d} value were not introduced for correction was at one side of the horizontal axis, and the degree of deviation from the horizontal axis in the dSOC curve increased with time; but a dSOC curve in which the K_{c} value and K_{d} value were introduced for correction almost coincided with the horizontal axis.

What is claimed is:

1. A method for calculating a remaining capacity of a power battery pack, comprising steps of:
(1) performing charging and discharging tests on a power battery pack provided with a battery management system with a charge-discharge machine;
(2) reading a charging capacity cumulative integral value C_{Bench}_{_{—}}_{c} of the charge-discharge machine and a discharging capacity cumulative integral value C_{Bench}_{_{—}}_{d} of the charge-discharge machine from a host computer of the charge-discharge machine, and reading a charging capacity cumulative integral value C_{BMS}_{_{—}}_{c} of the battery management system and a discharging capacity cumulative integral value C_{BMS}_{_{—}}_{d} of the battery management system from a CAN message of the battery management system;
(3) determining a charging correction coefficient K_{c} and a discharging correction coefficient K_{d},
where
the charging correction coefficient K_{c} is:
$${K}_{c} = \frac{{C}_{Bench\_c}}{{C}_{BMS\_c}}$$
the discharging correction coefficient K_{d} is:
$${K}_{d} = \frac{{C}_{Bench\_d}}{{C}_{BMS\_d}} ;$$
(4) determining a remaining capacity of the power battery pack:
when the power battery pack is in a charged state, a variation of capacity ΔC_{c} of the power battery pack after a time quantum Δt is ΔC_{c}=K_{c}×I×Δt, where, I is a charging current flowing through the power battery pack, the remaining capacity Cₜ of the power battery pack is obtained by calculating by Cₜ=C₀+ΔC_{c};
when the power battery pack is in a discharged state, a variation of capacity ΔC_{d} of the power battery pack after a time quantum Δt is ΔC_{d}=K_{d}×I×Δt, where, I is a discharging current flowing through the power battery pack, the remaining capacity Cₜ of the power battery pack is obtained by calculating by Cₜ=C₀−ΔC_{d}.

2. The method for calculating the remaining capacity of the power battery pack according to claim 1, wherein a current of the charge-discharge machine is 0 C˜1 C.

3. The method for calculating the remaining capacity of the power battery pack according to claim 1, wherein the charging and discharging tests are cycles of full charging and full discharging.

4. The method for calculating the remaining capacity of the power battery pack according to claim 1, wherein values of K_{c} and K_{d} are 0.8˜1.2.

5. The method for calculating the remaining capacity of the power battery pack according to claim 4, wherein when the values of K_{c} and K_{d} are not within the range of 0.8˜1.2, the values of K_{c} and K_{d} are 1 as default.
